(19) United States
(12) Patent Application Publication
(10) Pub. No.: US 2014/0035594 A1
(43) Pub. Date: Feb. 6, 2014

(54) ELECTRIC LEAKAGE DETECTING APPRATUS

(71) Applicant: KEIHIN CORPORATION, TOKYO (JP)

(72) Inventors: Seiji KAMATA, Utsunomiya-shi (JP); Shinichi SATO, Utsunomiya-shi (JP)

(73) Assignee: KEIHIN CORPORATION, TOKYO (JP)

(21) Appl. No.: 13/951,986

(22) Filed: Jul. 26, 2013

(30) Foreign Application Priority Data
Jul. 31, 2012 (JP) 2012-169790

(51) Int. Cl. G01R 31/02

(52) U.S. Cl. CPC G01R 31/025
USPC 324/509

(57) ABSTRACT

An electric leakage detecting apparatus is provided with: a first protective resistor in which one end is connected to the positive terminal of a battery; a first detecting resistor in which one end is connected to the other end of the first protective resistor; a second detecting resistor in which one end is connected to the other end of the first detecting resistor; a second protective resistor in which one end is connected to the other end of the second detecting resistor, and the other end is connected to the negative terminal of the battery; a chassis ground that is connected to one end of the second detecting resistor; a switch for applying a reference voltage to one end of the second detecting resistor at an arbitrary timing; and an electric leakage determining circuit that determines the presence of an electric leakage at a midpoint of the battery.

### CROSS-REFERENCE TO RELATED APPLICATION

Priority is claimed on Japanese Patent Application No. 2012-169790, filed Jul. 31, 2012, the content of which is incorporated herein by reference.

### BACKGROUND

1. Field of the Invention

The present invention relates to an electric leakage detecting apparatus.

2. Description of Related Art

As is well known, vehicles such as electric vehicles and hybrid vehicles are equipped with a motor, which becomes the source of power, and a high voltage and large capacity battery that supplies electric power to the motor. This high voltage battery is one configured by serially connecting a plurality of battery cells comprising lithium ion batteries or hydrogen nickel batteries, or the like. Such high voltage batteries for driving a motor are insulated from the chassis ground for safety. Therefore it is very important to detect insulation breakdowns (that is to say, to detect electric leakage) between the high voltage battery and the chassis ground. po Japanese Unexamined Patent Application, First Publication No. Hei 6-308185 discloses a technique in which there is provided a plurality of protective resistors and two detecting resistors that are respectively serially connected to the positive electrode side and the negative electrode side of a battery, and a plurality of switches that short circuit or open both ends of the protective resistors. Leakage is detected from the voltage across both ends of the two detecting resistors which are mutually connected and have their connection portions grounded to the chassis ground, or from the measured value of the electric current flowing therein.

### SUMMARY

In the technique described in Japanese Unexamined Patent Application, First Publication No. Hei 6-308185, in a case where an electric leakage is generated at the midpoint of the battery (that is to say, in a case where insulation breakdown has occurred between the midpoint of the battery and the chassis ground), the midpoint voltage of the battery and the voltage across the two detecting resistors are equal. Therefore there is a possibility that the electric leakage cannot be detected.

Aspects according to the present invention take into consideration the above circumstances, with an object of providing an electric leakage detecting apparatus in which it is possible to accurately detect electric leakage generated at the midpoint of a battery.

The aspects of the present invention employ the following configuration in order to solve the above problems.

(1) An electric leakage detecting apparatus of one aspect according to the present invention is provided with: a first protective resistor in which one end is connected to the positive terminal of a battery; a first detecting resistor in which one end is connected to the other end of the first protective resistor; a second detecting resistor in which one end is connected to the other end of the first detecting resistor; a second protective resistor in which one end is connected to the other end of the second detecting resistor, and the other end is connected to the negative terminal of the battery; and a chassis ground that is connected to one end of the second detecting resistor. The electric leakage detecting apparatus detects electric leakage from the battery which is insulated from the chassis ground, and is provided with: a switch for applying a reference voltage to one end of the second detecting resistor at an arbitrary timing; and an electric leakage determining circuit that, in a state in which the reference voltage is applied to one end of the second detecting resistor due to control of the switch, detects a voltage of one end of the first detecting resistor as a first voltage, and detects a voltage of the other end of the second detecting resistor as a second voltage, and based on the detected values of the first and second voltages, determines the presence of an electric leakage at a midpoint of the battery.

(2) In the aspect of (1) above, the electric leakage determining circuit may, in a state in which the reference voltage is applied to one end of the second detecting resistor, detect the first and second voltages, and in a case where the first voltage is more than a first threshold and the second voltage is less than a second threshold, determine that there is an electric leakage at the midpoint of the battery.

(3) In the aspect of (1) or (2) above, the electric leakage determining circuit may, in a state in which the reference voltage is not applied to one end of the second detecting resistor, detect the first and second voltages, and based on the detected values of the first and second voltages, determine the presence of an electric leakage on the positive electrode side or on the negative electrode side of the battery.

(4) In the aspect of (3) above, the electric leakage determining circuit may, in a state in which the reference voltage is not applied to one end of the second detecting resistor, detect the first and second voltages, and in a case where the first voltage is more than a third threshold and the second voltage is more than a fourth threshold, determine that there is an electric leakage on the negative electrode side of the battery, and on the other hand, in a case where the first voltage is less than the third threshold and the second voltage is less than the fourth threshold, determine that there is an electric leakage on the positive electrode side of the battery.

(5) In any one of the aspects from (1) to (4) above, there may be provided a third protective resistor positioned between one end of the second detecting resistor and the chassis ground.

In the electric leakage detecting apparatus of the above aspects according to the present invention, in a state in which the reference voltage is applied to one end of the second detecting resistor, a characteristic phenomenon is generated in which the smaller the insulation resistance between the battery midpoint and the chassis ground becomes, the first voltage rises, and on the other hand, the second voltage declines. Consequently, by determining of the presence of an electric leakage at the midpoint of the battery based on the detected values of the first and second voltages, it becomes possible to accurately detect electric leakage generated at the midpoint of the battery.

### BRIEF DESCRIPTION OF THE DRAWINGS

FIG. 1 is a schematic block diagram of an electric leakage detecting apparatus 1 of an embodiment according to the present invention.

FIG. 2 is a drawing A showing the type of path along which an electric current flows in the electric leakage detecting apparatus 1, in a case where an electric leakage is generated on a positive electrode side of a high voltage battery BT in a state in which a switch SW is OFF, and a drawing B showing the relationship between a first voltage VH, a second voltage VL, and insulation resistance RL_H in a case where an electric current flows along that path.

FIG. 3 is a drawing A showing the type of path along which an electric current flows in the electric leakage detecting apparatus 1, in a case where an electric leakage is generated on a negative electrode side of the high voltage battery BT in a state in which the switch SW is OFF, and a drawing B showing the relationship between the first voltage VH, the second voltage VL, and the insulation resistance RL L in a case where an electric current flows along that path.

FIG. 4 is a drawing A showing the type of path along which an electric current flows in the electric leakage detecting apparatus 1, in a case where an electric leakage is generated at a midpoint of the high voltage battery BT in a state in which the switch SW is ON, and a drawing B showing the relationship between the first voltage VH, the second voltage VL, and the insulation resistance RL_M in a case where an electric current flows along that path.

### DESCRIPTION OF THE EMBODIMENT

Herein, an embodiment of the present invention is described with reference to the drawings.

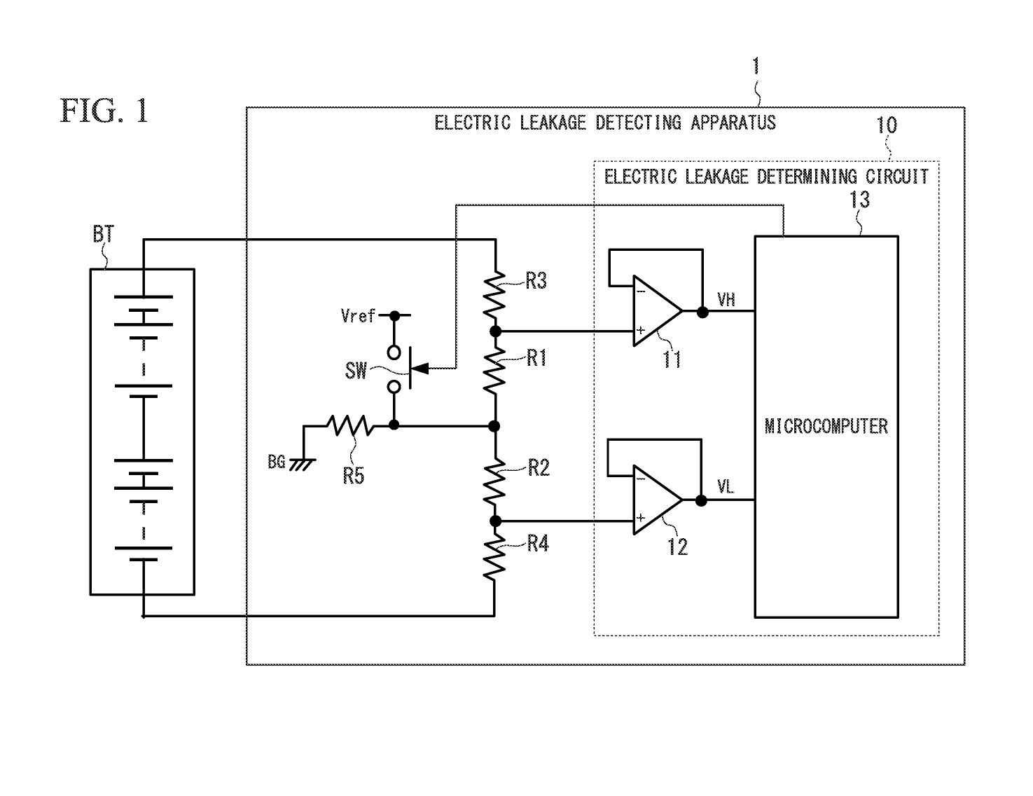

FIG. 1 is a schematic block diagram of an electric leakage detecting apparatus 1 according to the present embodiment. The electric leakage detecting apparatus 1 is one that detects electric leakage of a high voltage battery BT for driving a motor that is insulated from a chassis ground BG, and is provided with a first detecting resistor R1, a second detecting resistor R2, a first protective resistor R3, a second protective resistor R4, a third protective resistor R5, a switch SW, and an electric leakage determining circuit 10.

One end of the first protective resistor R3 is connected to the positive terminal of the high voltage battery BT, and the other end is connected to one end of the first detecting resistor R1. One end of the first detecting resistor R1 is connected to the other end of the first protective resistor R3, and the other end is connected to one end of the second detecting resistor R2. One end of the second detecting resistor R2 is connected to the other end of the first detecting resistor R1, and the other end is connected to one end of the second protective resistor R4. One end of the second protective resistor R4 is connected to the other end of the second detecting resistor R2, and the other end is connected to the negative terminal of the high voltage battery BT. One end of the third protective resistor R5 is connected to the other end of the first detecting resistor R1 and one end of the second detecting resistor R2, and the other end is connected to the chassis ground BG.

The switch SW is a semiconductor switching element, such as a MOSFET for example, for applying a reference voltage Vref to one end of the second detecting resistor R2 (the connection point between the first detecting resistor R1 and the second detecting resistor R2) at an arbitrary timing. Specifically, one end of the switch SW is connected to one end of the second detecting resistor R2, and the other end is connected to a reference voltage line to which a reference voltage Vref is applied. The reference voltage Vref may be one that is generated in an internal circuit of the electric leakage detecting apparatus 1, or it may be one that is supplied from an external apparatus.

The electric leakage determining circuit 10 is one that detects the voltage of one end of the first detecting resistor R1 as a first voltage VH, detects the voltage of the other end of the second detecting resistor R2 as a second voltage VL, and based on the detected values of the first and second voltages VH and VL, determines the presence of an electric leakage in the high voltage battery BT. It is provided with a first amplifier circuit 11, a second amplifier circuit 12, and a microcomputer 13.

The first amplifier circuit 11 is, for example, an op-amp, and amplifies the first voltage VH and outputs it to the microcomputer 13. The second amplifier circuit 12 is, for example, an op-amp, and amplifies the second voltage VL and outputs it to the microcomputer 13. The microcomputer 13 converts the first voltage VH input from the first amplifier circuit 11 and the second voltage VL input from the second amplifier circuit 12 into digital values, and determines the presence of an electric leakage in the high voltage battery BT based on the digital values, that is to say, the detected values of the first and second voltages VH and VL. Furthermore, the microcomputer 13 also has a function of controlling the ON/OFF of the switch SW.

Hereunder, is a description of the operation of the electric leakage detecting apparatus 1 constituted as described above.

When the microcomputer 13 of the electric leakage detecting apparatus 1 begins the electric leakage detection process, at first, in a state in which the switch SW is controlled to OFF (that is to say, in a state in which the reference voltage Vref is not applied to one end of the second detecting resistor R2), it converts the first voltage VH input from the first amplifier circuit 11 and the second voltage VL input from the second amplifier circuit 12 into digital values to thereby obtain the detected values of the first and second voltages VH and VL.

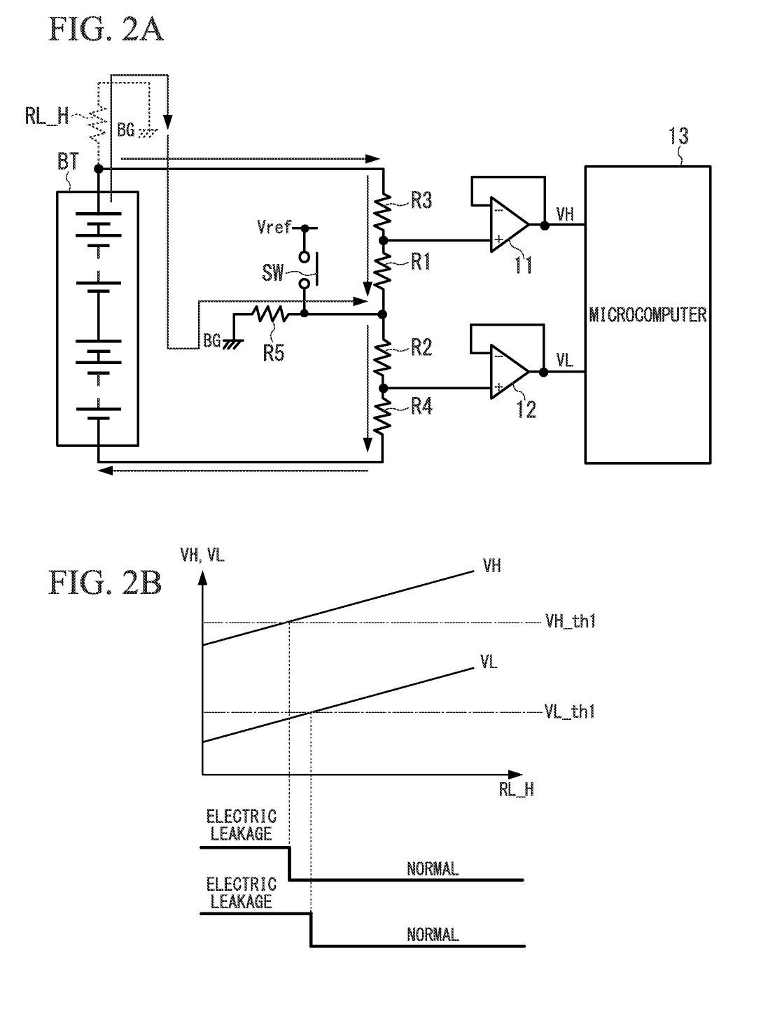

FIG. 2A is a drawing showing the type of path along which an electric current flows in the interior of the electric leakage detecting apparatus 1, in a case where an electric leakage is generated on the positive electrode side of the high voltage battery BT in a state in which the switch SW is OFF. In FIG. 2A, reference symbol RL_H represents the insulation resistance between the positive terminal of the high voltage battery BT, and the chassis ground BG.

As shown in FIG. 2A, in a case where an electric leakage is generated on the positive electrode side of the high voltage battery BT in a state in which the switch SW is OFF, the electric current flows along a path of the positive terminal of the high voltage battery BT→the insulation resistance RL_H→the chassis ground BG→the third protective resistor R5→the second detecting resistor R2→the second protective resistor R4→the negative terminal of the high voltage battery BT, and a path of; the positive terminal of the high voltage battery BT→the first protective resistor R3→the first detecting resistor R1→the second detecting resistor R2→the second protective resistor R4→the negative terminal of the high voltage battery BT.

FIG. 2B is a drawing showing the relationship between the first voltage VH, the second voltage VL, and the insulation resistance RL_H in a case where the electric current flows along the above paths. As shown in FIG. 2B, the smaller the insulation resistance RL_H becomes, the first voltage VH and the second voltage VL decline while maintaining a fixed magnitude relationship (VH>VL). By utilizing such a phenomenon, in a case where the first voltage VH and the second voltage VL have respectively fallen below a threshold, it can be determined that an electric leakage has been generated on the positive electrode side of the high voltage battery BT.

That is to say, the microcomputer 13, in a case where as shown in FIG. 2B, the first voltage VH obtained in a state in which the switch SW is controlled to OFF is less than a threshold VH_th1 (third threshold), and the second voltage VL is less than a threshold VL_th1 (fourth threshold), determines that there is an electric leakage on the positive electrode side of the high voltage battery BT, and outputs the judgment result to the exterior. As shown in FIG. 2B, the threshold VH_th1 is set higher than the threshold VL_th1.

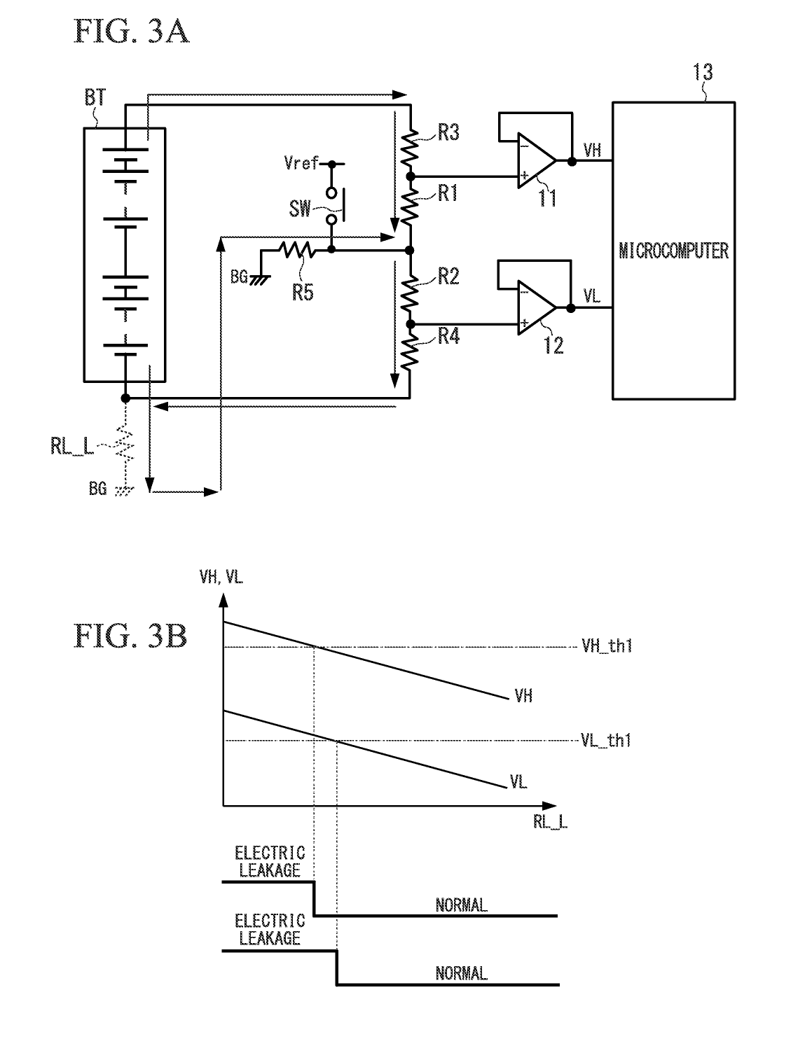

FIG. 3A is a drawing showing the type of path along which an electric current flows in the interior of the electric leakage detecting apparatus 1, in a case where an electric leakage is generated on the negative electrode side of the high voltage battery BT in a state in which the switch SW is OFF. In FIG. 3A, reference symbol RL_L represents the insulation resistance between the negative terminal of the high voltage battery BT, and the chassis ground BG.

As shown in FIG. 3A, in a case where an electric leakage is generated on the negative electrode side of the high voltage battery BT in a state in which the switch SW is OFF, the electric current flows along a path of the positive terminal of the high voltage battery BT→the first protective resistor R3→the first detecting resistor R1→the second detecting resistor R2→the second protective resistor R4→the negative terminal of the high voltage battery BT, and a path of; the negative terminal of the high voltage battery BT→the insulation resistance RL_L→the chassis ground BG→the third protective resistor R5→the second detecting resistor R2→the second protective resistor R4→the negative terminal of the high voltage battery BT.

FIG. 3B is a drawing showing the relationship between the first voltage VH, the second voltage VL, and the insulation resistance RL_L in a case where the electric current flows along the above paths. As shown in FIG. 3B, the smaller the insulation resistance RL_L becomes, the first voltage VH and the second voltage VL rise while maintaining a fixed magnitude relationship (VH>VL). By utilizing such a phenomenon, in a case where the first voltage VH and the second voltage VL have respectively become more than a threshold, it can be determined that an electric leakage has been generated on the negative electrode side of the high voltage battery BT.

That is to say, the microcomputer 13, in a case where as shown in FIG. 3B, the first voltage VH obtained in a state in which the switch SW is controlled to OFF is more than the threshold VH_th1, and the second voltage VL is more than the threshold VL_th1, determines that there is an electric leakage on the negative electrode side of the high voltage battery BT, and outputs the judgment result to the exterior.

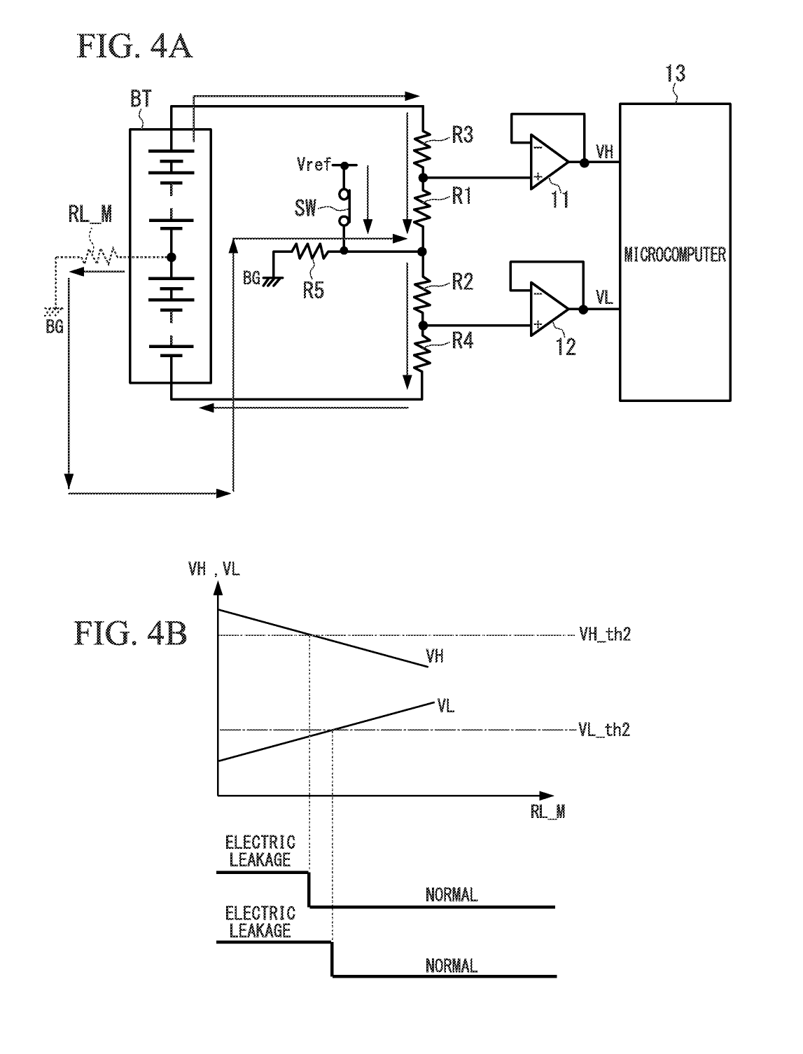

Incidentally, as mentioned above, in a state in which the switch SW is OFF, electric leakage generated on the positive electrode side or the negative electrode side of the high voltage battery BT can be detected. However, as shown in FIG. 4A, in a case where an electric leakage is generated at the midpoint of the high voltage battery BT, the first voltage VH and the second voltage VL become equal, and hence the presence of an electric leakage cannot be determined. Therefore, the microcomputer 13, in a case where the detected values of the first and second voltages VH and VL obtained in a state in which the switch SW is controlled to OFF are equal, switches the switch SW to ON.

Then, the microcomputer 13, in a state in which the switch SW is controlled to ON (that is to say, in a state in which the reference voltage Vref is applied to one end of the second detecting resistor R2), converts the first voltage VH input from the first amplifier circuit 11 and the second voltage VL input from the second amplifier circuit 12 into digital values, to thereby newly obtain the detected values of the first and second voltages VH and VL.

FIG. 4A is a drawing showing the type of path along which an electric current flows in the interior of the electric leakage detecting apparatus 1, in a case where an electric leakage is generated at the midpoint of the high voltage battery BT in a state in which the switch SW is ON. In FIG. 4A, the reference symbol RL_M represents the insulation resistance between the midpoint of the high voltage battery BT, and the chassis ground BG.

As shown in FIG. 4A, in a case where an electric leakage is generated at the midpoint of the high voltage battery BT in a state in which the switch SW is ON, the electric current flows along a path of; the midpoint of the high voltage battery BT→the insulation resistance RL_M→the chassis ground BG→the third protective resistor R5→the second detecting resistor R2→the second protective resistor R4→the negative terminal of the high voltage battery BT, and a path of; the positive terminal of the high voltage battery BT→the first protective resistor R3→the first detecting resistor R1→the second detecting resistor R2→the second protective resistor R4→the negative terminal of the high voltage battery BT. Furthermore, due to the switch SW becoming ON, the reference voltage Vref is applied to one end of the second detecting resistor R2.

FIG. 4B is a drawing showing the relationship between the first voltage VH, the second voltage VL, and the insulation resistance RL_M in a case where the electric current flows along the above paths. As shown in FIG. 4B, the smaller the insulation resistance RL_M becomes, the first voltage VH rises, and on the other hand, the second voltage VL declines. By utilizing such a phenomenon, in a case where the first voltage VH becomes more than a threshold and the second voltage VL becomes less than a threshold, it can be determined that an electric leakage has been generated at the midpoint of the high voltage battery BT.

That is to say, the microcomputer 13, in a case where as shown in FIG. 4B, the first voltage VH obtained in a state in which the switch SW is controlled to ON is more than a threshold VH_th2 (first threshold), and the second voltage VL is less than a threshold VL_th2 (second threshold), determines that there is an electric leakage at the midpoint of the high voltage battery BT, and outputs the judgment result to the exterior. When the microcomputer 13 switches the switch SW to ON, the threshold VH_th2 is set higher than the threshold VH_th1, and the threshold VL_th2 is set higher than the threshold VL_th1.

In the above manner, according to the electric leakage detecting apparatus 1 of the present embodiment, electric leakage of the high voltage battery BT can be detected, and it becomes possible to accurately detect electric leakage generated at the midpoint of the high voltage battery BT, the detection of which was conventionally particularly problematic.

The present invention is in no way limited to the embodiment mentioned above. For example, in FIG. 1, the first detecting resistor R1, the second detecting resistor R2, the first protective resistor R3, the second protective resistor R4, and the third protective resistor R5 are respectively illustrated as though they consist of single resistance elements. However they may be made to consist of a plurality of resistance elements that are serially connected or connected in parallel.

What is claimed is:

1. An electric leakage detecting apparatus provided with:
a first protective resistor in which one end is connected to the positive terminal of a battery;
a first detecting resistor in which one end is connected to the other end of the first protective resistor;
a second detecting resistor in which one end is connected to the other end of the first detecting resistor;
a second protective resistor in which one end is connected to the other end of the second detecting resistor, and the other end is connected to the negative terminal of the battery; and
a chassis ground that is connected to one end of the second detecting resistor, wherein the electric leakage detecting apparatus detects electric leakage from the battery which is insulated from the chassis ground, and is provided with:
a switch for applying a reference voltage to one end of the second detecting resistor at an arbitrary timing; and
an electric leakage determining circuit that, in a state in which the reference voltage is applied to one end of the second detecting resistor due to control of the switch, detects a voltage of one end of the first detecting resistor as a first voltage, and detects a voltage of the other end of the second detecting resistor as a second voltage, and based on the detected values of the first and second voltages, determines the presence of an electric leakage at a midpoint of the battery.

2. An electric leakage detecting apparatus according to claim 1, wherein the electric leakage determining circuit, in a state in which the reference voltage is applied to one end of the second detecting resistor, detects the first and second voltages, and in a case where the first voltage is more than a first threshold and the second voltage is less than a second threshold, determines that there is an electric leakage at the midpoint of the battery.

3. An electric leakage detecting apparatus according to claim 1, wherein the electric leakage determining circuit, in a state in which the reference voltage is not applied to one end of the second detecting resistor, detects the first and second voltages, and based on the detected values of the first and second voltages, determines the presence of an electric leakage on the positive electrode side or on the negative electrode side of the battery.

4. An electric leakage detecting apparatus according to claim 3, wherein the electric leakage determining circuit, in a state in which the reference voltage is not applied to one end of the second detecting resistor, detects the first and second voltages, and in a case where the first voltage is more than a third threshold and the second voltage is more than a fourth threshold, determines that there is an electric leakage on the negative electrode side of the battery, and on the other hand, in a case where the first voltage is less than the third threshold and the second voltage is less than the fourth threshold, determines that there is an electric leakage on the positive electrode side of the battery.

5. An electric leakage detecting apparatus according to claim 1, wherein there is provided a third protective resistor positioned between one end of the second detecting resistor and the chassis ground.
